(19) United States
(12) Patent Application Publication
(10) Pub. No.: US 2026/0157120 A1
(43) Pub. Date: Jun. 4, 2026

(54) SEMICONDUCTOR DEVICE AND METHOD FOR FABRICATING THE SAME

(71) Applicant: SK hynix Inc., Gyeonggi-do (KR)

(72) Inventors: Jeong Myeong KIM, Gyeonggi-do (KR); Cha Deok DONG, Gyeonggi-do (KR); Keo Rock CHOI, Gyeonggi-do (KR)

(21) Appl. No.: 19/243,002

(22) Filed: Jun. 19, 2025

(30) Foreign Application Priority Data
Nov. 29, 2024 (KR) 10-2024-0174416

(51) Int. Cl. H10N 70/20; H10B 63/00; H10N 70/00

(52) U.S. Cl. CPC H10N 70/25; H10B 63/20; H10N 70/023; H10N 70/043; H10N 70/826; H10N 70/841; H10N 70/884

(57) ABSTRACT

Disclosed are a semiconductor device and a method for fabricating the semiconductor device. The semiconductor device includes a plurality of memory cells, wherein each memory cell of said plurality of memory cells includes a memory layer; a selector layer disposed over the memory layer to select the memory layer, the selector layer including an amorphous silicon layer including a dopant containing a group-13 element and a group-15 element of a periodic table; and a barrier layer containing boron (B) disposed over or below the selector layer.

### CROSS-REFERENCE TO RELATED APPLICATIONS

The present application claims priority under 35 U.S.C 119(a) to Korean Patent Application No. 10-2024-0174416, filed on Nov. 29, 2024, which is incorporated herein by reference in its entirety.

### BACKGROUND

### 1. Field

Embodiments of the present disclosure relate to a semiconductor technology, and more particularly, to a semiconductor device including a memory cell with a selector, and a method for fabricating the semiconductor device.

### 2. Description of the Related Art

Recent demands for miniaturization, low power consumption, high performance, and diversification of electronic devices require semiconductor devices capable of storing data in diverse electronic devices, such as computers, portable communication devices and the like, and researchers and the industry are studying to develop such semiconductor devices. Such semiconductor devices include those capable of storing data by using the characteristics of switching between different resistance states according to the applied voltage or current, such as a Resistive Random Access Memory (RRAM), a Phase-change Random Access Memory (PRAM), a Ferroelectric Random Access Memory (FRAM), a Magnetic Random Access Memory (MRAM), an E-fuse and the like.

A memory device having a variable resistance element may include a selector as an element for selecting a particular memory cell among a plurality of memory cells that are arrayed, and the selector may be realized as a thin layer in a memory cell.

### SUMMARY

Embodiments of the present disclosure are directed to a semiconductor device capable of improving the selector characteristics of a memory cell, and a method for fabricating the semiconductor device.

In accordance with an embodiment of the present disclosure, a semiconductor device includes a plurality of memory cells, wherein each memory cell of said plurality of memory cells includes a memory layer; a selector layer disposed over the memory layer to select the memory layer, the selector layer including an amorphous silicon layer including a dopant containing a group-13 element and a group-15 element of a periodic table; and a barrier layer containing boron (B) disposed over or below the selector layer.

In accordance with another embodiment of the present disclosure, a method for fabricating a semiconductor device including a selector layer for controlling electrical access to a memory cell includes forming, as the selector layer, an amorphous silicon layer including a dopant over a substrate; and forming a barrier layer containing boron (B) at an upper portion or a lower portion of the selector layer through a plasma treatment.

### BRIEF DESCRIPTION OF THE DRAWINGS

FIGS. 1A and 1B illustrate a semiconductor device in accordance with an embodiment of the present disclosure.

FIG. 2 is a cross-sectional view illustrating a structure of a selector unit in accordance with the embodiment of the present disclosure.

FIG. 3 illustrates an operation of the selector unit shown in FIG. 2.

FIGS. 4A to 4H are cross-sectional views illustrating a semiconductor device and a fabrication method thereof in accordance with an embodiment of the present disclosure.

### DETAILED DESCRIPTION

Hereinafter, the various embodiments of the present disclosure will be described in detail with reference to the attached drawings.

Embodiments of the present disclosure will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate. When a first element is referred to as being “over” a second element, it not only refers to a case where the first element is formed directly on the second element but also a case where a third element exists between the first element and the second element.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present disclosure.

In addition, it will also be understood that when an element is referred to as being “between” two elements, it may be the only element between the two elements, or one or more intervening elements may also be present.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

It should be understood that the drawings are simplified schematic illustrations of the described devices and may not include well known details to avoid obscuring the features of the embodiments.

It should also be noted that features present in one embodiment may be used with one or more features of another embodiment without departing from the scope of the present disclosure.

As used herein, singular forms are intended to include the plural forms as well, unless the context clearly indicates otherwise.

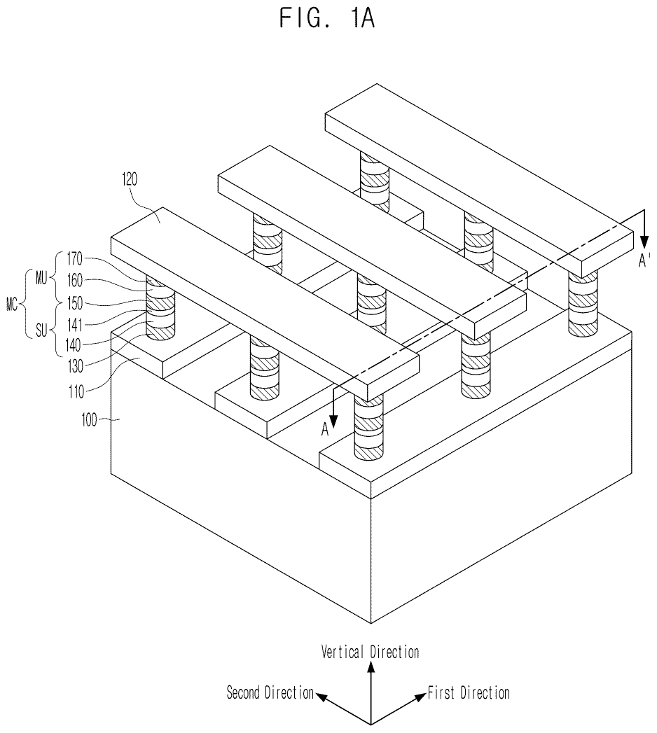

FIGS. 1A and 1B illustrate a semiconductor device in accordance with an embodiment of the present disclosure. FIG. 1A is a perspective view of the semiconductor device, and FIG. 1B is a cross-sectional view taken along a line A-A′ shown in FIG. 1A.

Referring to FIGS. 1A and 1B, the semiconductor device in accordance with the embodiment of the present disclosure may include a substrate 100, a plurality of first interconnections 110 disposed over the substrate 100 and extending in a first direction, a plurality of second interconnections 120 disposed over the first interconnections 110 and extending in a second direction intersecting with the first direction, and a plurality of memory cells MC disposed between the first interconnections 110 and the second interconnections 120 to respectively overlap with the intersection regions between the first interconnections 110 and the second interconnections 120. The first direction and the second direction may mean directions substantially parallel to the surface of the substrate 100. A direction substantially perpendicular to the surface of the substrate 100 may be, hereinafter, referred to as a vertical direction.

The substrate 100 may include a semiconductor material, such as silicon. A required predetermined lower structure (not shown) may be formed in the substrate 100. For example, an integrated circuit for driving the first interconnection 110 and/or the second interconnection 120 may be formed in the substrate 100.

A plurality of first interconnections 110 may be arranged spaced apart from each other in the second direction. The first interconnection 110 may include diverse conductive materials, for example, metals such as platinum (Pt), tungsten (W), aluminum (Al), copper (Cu), tantalum (Ta) and the like, metal nitrides such as titanium nitride (TiN), tantalum nitride (TaN) and the like, or combinations thereof, and the first interconnections 110 may have a single-layer structure or a multi-layer structure.

A plurality of second interconnections 120 may be arranged spaced apart from each other in the first direction. The second interconnection 120 may include diverse conductive materials, for example, metals such as platinum (Pt), tungsten (W), aluminum (Al), copper (Cu), tantalum (Ta) and the like, metal nitrides such as titanium nitride (TiN), tantalum nitride (TaN) and the like, or combinations thereof, and the second interconnections 120 may have a single-layer structure or a multi-layer structure. The first interconnections 110 may function as word lines, and the second interconnections 120 may function as bit lines, or the first interconnections 110 may function as bit lines, and the second interconnections 120 may function as word lines. Although a cross-point structure of one layer is described in this embodiment of the present disclosure, the cross-point structure may be formed of two or more layers that are stacked in the vertical direction.

Each of the memory cells MC may include a memory unit MU which is a portion where data are actually stored, and a selector unit SU that controls access to the memory unit MU. For example, the memory cell MC may include a stacked structure of a first electrode layer 130, a selector layer 140, a second electrode layer 150, a memory layer 160, and a third electrode layer 170. Here, the selector unit SU may include the first electrode layer 130, the selector layer 140, and the second electrode layer 150, and the memory unit MU may include the second electrode layer 150, the memory layer 160, and the third electrode layer 170. The second electrode layer 150 may be shared by the selector unit SU and the memory unit MU.

The first electrode layer 130 and the third electrode layer 170 may be disposed at both ends of the memory cell MC, that is, at the bottom and the top ends of the memory cell MC, respectively, and may function to transfer a voltage or current required for an operation of the memory cell MC. The second electrode layer 150 may function to electrically connect the selector layer 140 and the memory layer 160 to each other while physically separating them from each other. The first electrode layer 130, the second electrode layer 150, or the third electrode layer 170 may include diverse conductive materials, for example, metals such as platinum (Pt), tungsten (W), aluminum (Al), copper (Cu), tantalum (Ta), titanium (Ti) and the like, metal nitrides such as titanium nitride (TiN), tantalum nitride (TaN) and the like, or combinations thereof. The first electrode layer 130, the second electrode layer 150, or the third electrode layer 170 may include a carbon electrode.

The memory layer 160 may function to store data in diverse ways. For example, the memory layer 160 may include a memory layer that stores different data by switching between different resistance states according to the voltage or current supplied through the upper and lower ends of the memory layer 160. The memory layer may have a single-layer structure or a multi-layer structure including diverse materials used in a Resistive Random Access Memory (RRAM), a Phase-change Random Access Memory (PRAM), a Ferroelectric Random Access Memory (FRAM), a Magnetic Random Access Memory (MRAM) and the like, for example, metal oxides such as transition metal oxides, perovskite-based materials and the like, phase-change materials such as chalcogenide-based materials and the like, ferroelectric materials, ferromagnetic materials, and the like.

The memory layer 160 may include a lower layer, a free layer, a tunnel barrier layer, a fixed layer, a magnetic compensation layer, and a capping layer.

The free layer may be a layer that may store different data by having a changeable magnetization direction, and the free layer may also be called a storage layer. The fixed layer may be a layer that may be contrasted with the magnetization direction of the free layer by having a fixed magnetization direction, and the fixed layer may also be called a reference layer and the like. The free layer and the fixed layer may have a single-layer structure or a multi-layer structure including a ferromagnetic material. For example, the free layer and the fixed layer may include an alloy mainly containing Fe, Ni or Co, such as an Fe—Pt alloy, an Fe—Pd alloy, a Co—Pd alloy, a Co—Pt alloy, an Fe—Ni—Pt alloy, a Co—Fe—Pt alloy, a Co—Ni—Pt alloy, an Fe—Pd alloy, a Co—Pd alloy, a Co—Pt alloy, an Fe—Ni—Pt alloy, a Co—Fe—Pt alloy, a Co—Ni—Pt alloy, a Co—Fe—B alloy, or the like, or may include a stacked structure such as Co/Pt, Co/Pd, and the like. The magnetization directions of the free layer and the fixed layer may be substantially perpendicular to the layer surfaces. The magnetization direction of the free layer may vary between a top-down direction and a bottom-up direction, and the magnetization direction of the fixed layer may be fixed in a top-down direction or a bottom-up direction. This magnetization direction of the free layer may be changed due to the spin transfer torque. The relative positions of the free layer and the fixed layer may vary diversely with the tunnel barrier layer interposed therebetween. For example, the fixed layer may be disposed below the tunnel barrier layer, and the free layer may be disposed over the tunnel barrier layer.

The tunnel barrier layer may enable tunneling of electrons between the free layer and the fixed layer during a write operation that changes the resistance state of the variable resistance element, thereby changing the magnetization direction of the free layer. The tunnel barrier layer may include a dielectric oxide, such as MgO, CaO, SrO, TiO, VO, NbO, and the like. The free layer, the tunnel barrier layer, and the fixed layer may form a Magnetic Tunnel Junction (MTJ) structure.

The selector layer 140 may be realized as a thin layer in the memory cell, and the selector layer 140 may function to prevent current leakage that may occur between the memory cells MC that share the first interconnection 110 or the second interconnection 120, while controlling electrical access to one memory cell among the arrayed memory cells. To this end, the selector layer 140 may have threshold switching characteristics of blocking off the current or holding the current to hardly flow when the level of the voltage supplied to the upper and lower ends of the selector layer 140 is below a predetermined threshold voltage level, and then letting the current flow rapidly at a voltage level which is equal to or higher than the threshold voltage level. The selector layer 140 may be turned on at a voltage level which is equal to or higher than the threshold voltage level and turned off at a voltage level which is lower than the threshold voltage level. For example, the selector layer 140 may include a dielectric material into which a dopant is implanted. According to a preferred embodiment of the present disclosure, the selector layer 140 may include an amorphous silicon layer that is doped with boron (B). For another example, the selector layer 140 may be the amorphous silicon layer that is doped with boron and additionally doped with arsenic (As) by an additional ion implantation process.

According to the embodiments of the present disclosure, the dopant doped into the amorphous silicon layer may be a group-13 element of the periodic table instead of boron (B), and may be a group-14 element or a group-15 element of the periodic table instead of arsenic (As).

A boron barrier layer 141 may be formed over the selector layer 140. The boron barrier layer 141 may serve as a charge trap site, and in particular, the boron barrier layer 141 may activate a hole trap site to effectively capture a charge and contribute to controlling the operation characteristics of the selector layer 140. When the hole trap site is activated, the migration path of electrons may be set more clearly, thereby improving the electron mobility and facilitating a smoother current flow. The initial resistance may increase due to the boron barrier layer 141, thereby reducing the off current in the off-state of the selector layer 140 and improving the energy efficiency of the selector layer 140. During the operation, the boron barrier layer 141 may utilize the trap site to form a conduction path more easily in the on-state. This may reduce the threshold voltage and enable the selector layer 140 to be switched at a lower voltage level. Furthermore, the boron barrier layer 141 may stably maintain the arsenic (As) profile of the selector layer 140 by maintaining the performance of the selector layer 140 for a long time, and the boron barrier layer 141 may further reduce the threshold voltage level Vₜₕ as an effect of interposing an auxiliary layer.

However, the embodiment of the present disclosure is not limited thereto, and the boron barrier layer 141 may be formed not only in the upper portion of the selector layer 140 but also in the lower portion of the selector layer 140, which may have another effect on the operation characteristics of the selector layer 140. When the boron barrier layer 141 is disposed in the lower portion of the selector layer 140, the charge trap site may contribute to the formation of the initial characteristics of the selector layer 140, thereby further improving the physical and electrical stabilities of the selector layer 140. In particular, the boron barrier layer 141 disposed in the lower portion of the selector layer 140 may function to control the distribution of arsenic (As), boron (B), and other doping elements that are doped or ion-implanted into the selector layer 140.

Referring to FIGS. 1A and 1B, the memory cell MC may include a stacked structure of a first electrode layer 130, a selector layer 140, a second electrode layer 150, a memory layer 160, and a third electrode layer 170, but the concepts and scope of the present disclosure are not limited thereto, and the layer structure of the memory cell MC may be diversely modified. For example, at least one of the first electrode layer 130, the second electrode layer 150, and the third electrode layer 170 may be omitted. For example, the memory cell MC may include a selector layer 140, a first electrode layer 130 disposed below the selector layer 140, and a third electrode layer 170 disposed over the selector layer 140. For example, the first electrode layer 130 disposed below the selector layer 140 may include titanium nitride (TiN), and the third electrode layer 170 disposed over the selector layer 140 may include a carbon (C) electrode. For example, the upper and lower positions of the selector layer 140 and the memory layer 160 may be switched. Further, the memory cell MC may further include one or more layers (not shown) to improve characteristics or process.

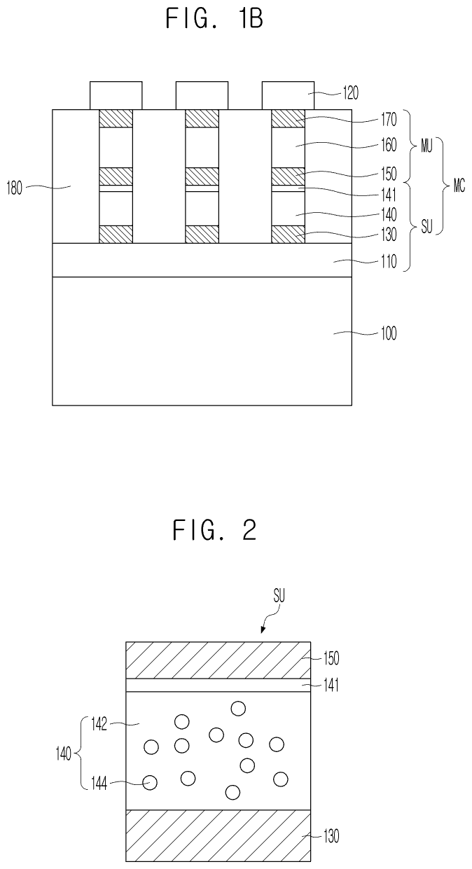

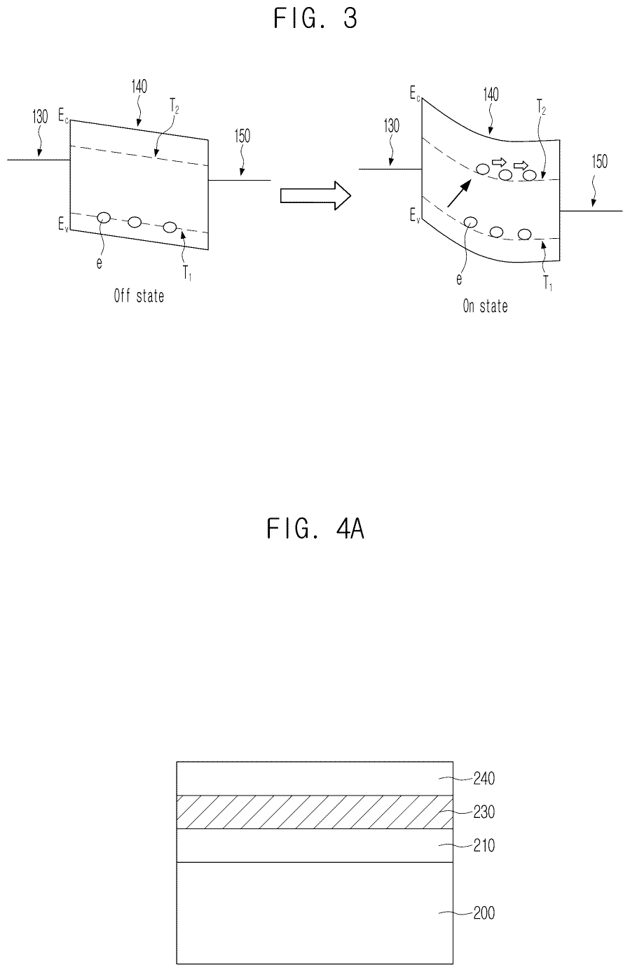

The selector unit SU including the selector layer 140 and the boron barrier layer 141 and the operation of the selector unit SU will be described in detail by referring to FIGS. 2 and 3 below.

FIG. 2 is a cross-sectional view illustrating a structure of the selector unit SU in accordance with the embodiment of the present disclosure.

Referring to FIG. 2, the selector unit SU may include a first electrode layer 130, a selector layer 140, a boron barrier layer 141, and a second electrode layer 150.

As described above, the first electrode layer 130 and the second electrode layer 150 may include diverse conductive materials, such as metals, metal nitrides, and the like. The first electrode layer 130 and the second electrode layer 150 may be formed of the same material, and thus they may have the same work function. For example, the first electrode layer 130 and the second electrode layer 150 may include titanium nitride (TiN) having a work function of approximately 4.4 to 4.6 eV. However, the concepts and scope of the present disclosure are not limited thereto, and the first electrode layer 130 and the second electrode layer 150 may be formed of different materials, and thus they may have different work functions.

The selector layer 140 may include a dielectric material layer 142, and a dopant 144 which is implanted into the dielectric material layer 142.

The dielectric material layer 142 may include a dielectric material having a relatively wide band gap, for example, a dielectric material having a band gap of approximately 5.0 eV or higher. For example, the dielectric material layer 142 may include a silicon-containing dielectric material such as silicon oxide, silicon nitride, silicon oxynitride, and the like, a dielectric metal oxide, a dielectric metal nitride, or a combination thereof. For example, an oxide layer such as silicon dioxide (SiO₂) may be formed by mixing source gases containing silicon (Si) and oxygen (O) by a method, such as Chemical Vapor Deposition (CVD), Physical Vapor Deposition (PVD), or Atomic Layer Deposition (ALD). There may be a deep trap whose energy level is closer to the energy level of a valence band than to the energy level of a conduction band of the dielectric material layer 142 in the dielectric material layer 142. The dopant 144 may serve to create a shallow trap that provides a passage for conductive carriers, such as electrons or holes, to migrate in the dielectric material layer 142. The shallow trap may have an energy level which is closer to the energy level of the conduction band than to the energy level of the valence band of the dielectric material layer 142. The dopant doped into the selector layer 140 may include an n-type or p-type dopant and the dopant may be implanted by an ion implantation process. For example, when the dielectric material layer 142 contains silicon, the dopant 144 may include a group-13 element and a group-15 element of the periodic table having different valences from the valence of silicon (Si). For example, the dopant 144 may include a group-13 element of the periodic table, such as boron (B), aluminum (Al), gallium (Ga), or indium (In). For example, the dopant 144 may include a group-14 element of the periodic table, such as carbon (C), silicon (Si), germanium (Ge), or tin (Sn), together with a group-13 element of the periodic table. For example, the dopant 144 may include a group-15 element of the periodic table, such as nitrogen (N), phosphorus (P), arsenic (As), or antimony (Sb), together with a group-13 element of the periodic table. For example, the dopant 144 may include boron (B), and the dopant 144 may further include one or more among phosphorus (P) and arsenic (As) together with boron (B). Preferably, the dopant 144 may further include arsenic (As).

The dopant concentration and the ratio of amorphous silicon in the doped amorphous silicon layer may vary greatly according to the process conditions. The dopant concentration may be adjusted by controlling the flow rates and hydraulic pressures of diborane (B₂H₆) and silane gas (SiₓH_{y}). For example, the dopant concentration may be increased by increasing the flow rate of diborane, and conversely, the ratio of amorphous silicon may be increased by increasing the flow rate of silane gas. When a doped amorphous silicon layer is generated by reacting diborane and silane gases under the temperature condition of approximately 300° C., the dopant 144 in the doped amorphous silicon layer may have a concentration of approximately 10 to 30 wt %, and the amorphous silicon may have a concentration of approximately 90 to 70 wt %. When a doped amorphous silicon layer is generated by reacting diborane and silane gases under the temperature condition of approximately 400° C., the diffusion of the dopant may become more active to dope the amorphous silicon layer with the dopant more easily. Therefore, in this case, the dopant 144 in the doped amorphous silicon layer may have a concentration of approximately 30 to 90 wt %, and the amorphous silicon may have a concentration of approximately 70 to 10 wt %.

The boron barrier layer 141 may be disposed between the selector layer 140 and the second electrode layer 150 to serve as a charge trap site. In particular, the boron barrier layer 141 may effectively capture charges by activating the hole trap site and contribute to controlling the operation characteristics of the selector layer 140. When the hole trap site is activated, the migration path of electrons may be set more clearly, thereby improving electron mobility and facilitating the current to flow more smoothly.

The operation of the selector unit SU may be described below with reference to FIG. 3.

FIG. 3 illustrates an operation of the selector unit SU shown in FIG. 2. Referring to FIG. 3, in the off-state where no voltage is applied to the selector unit SU, a conductive carrier, for example, an electron (e), may be trapped in a deep trap T1 of the selector layer 140.

When a voltage which is equal to or higher than a threshold voltage level is applied to the selector unit SU in the off-state through the first electrode layer 130 and the third electrode layer 150, an on-state in which the current flows through the selector unit SU may be realized. To be more specific, when a voltage which is equal to or higher than the threshold voltage level is applied to the selector unit SU, a conductive carrier trapped in the deep trap T1 may jump to a shallow trap T2 by a thermal emission process or a tunneling process, and a conduction path coupling the first electrode layer 130 and the third electrode layer 150 may be created as the conductive carrier migrating through the shallow trap T2.

When the voltage applied to the selector unit SU in the on-state decreases, the number of the conductive carriers migrating from the deep trap T1 to the shallow trap T2 may also decrease so that the selector unit SU may go back to the off-state.

In this way, the selector unit SU may be turned on and off.

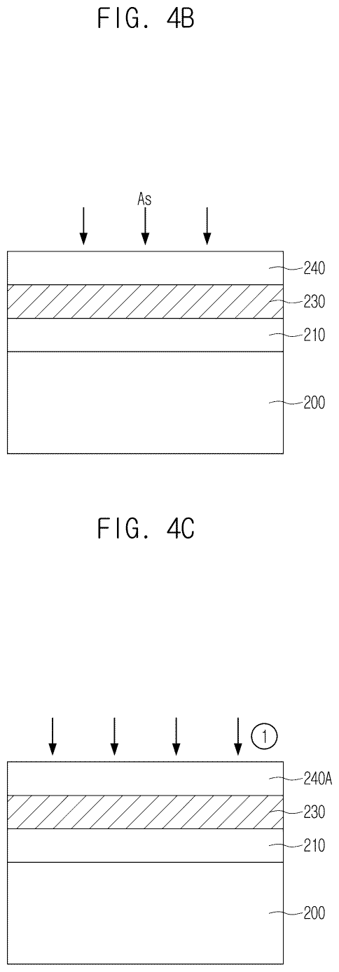

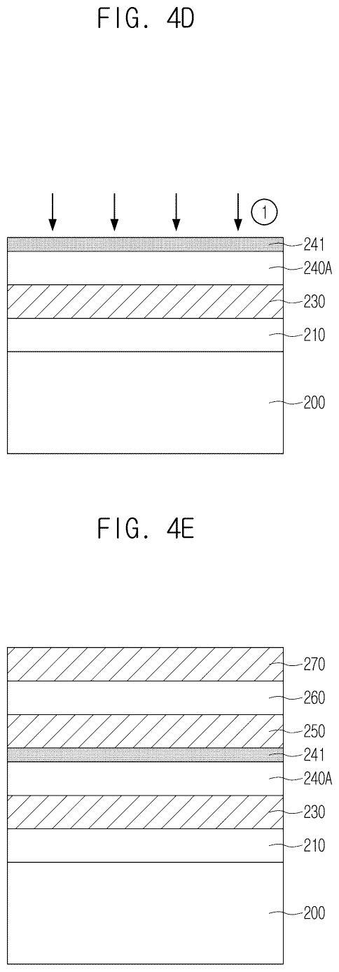

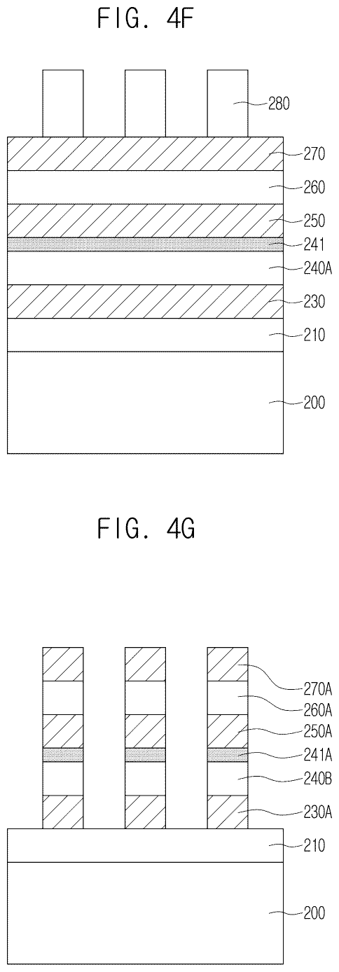

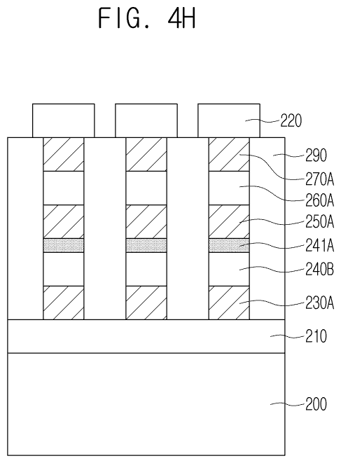

FIGS. 4A to 4H are cross-sectional views illustrating a semiconductor device and a fabrication method thereof in accordance with an embodiment of the present disclosure.

First, the method for fabricating the semiconductor device may be described below.

Referring to FIG. 4A, a substrate 200 including a predetermined lower structure formed therein may be provided. The substrate 200 may include required diverse circuits. A first interconnection 210 may be formed over the substrate 200. The first interconnection 210 may be formed by forming a gap-fill layer (not shown) having a trench for forming the first interconnection 210 over the predetermined structure and depositing a conductive layer for forming the first interconnection 210 in the trench. The first interconnection 210 may include diverse conductive materials, for example, metals such as platinum (Pt), tungsten (W), aluminum (Al), copper (Cu), tantalum (Ta) and the like, metal nitrides such as titanium nitride (TiN), tantalum nitride (TaN) and the like, or combinations thereof, and the first interconnection 210 may have a single-layer structure or a multi-layer structure.

Subsequently, a first electrode layer 230 may be formed over the first interconnection 210. The first electrode layer 230 may be realized as a TiN thin layer.

Subsequently, an amorphous silicon layer that is doped with a dopant may be formed as an initial selector layer 240 over the first electrode layer 230. Here, the method for forming the amorphous silicon layer that is doped with a dopant may be realized as a method for depositing the amorphous silicon layer that is doped with the first dopant. The first dopant may be a group-13 element of the periodic table, such as boron (B), aluminum (Al), gallium (Ga), or indium (In). Preferably, the first dopant may include boron (B).

The amorphous silicon layer including the first dopant may be formed by a Low-Pressure Chemical Vapor Deposition (LPCVD) process using a first dopant-containing catalyst and a silicon source gas. For example, the amorphous silicon layer including a first dopant may be formed by a Low-Pressure Chemical Vapor Deposition (LPCVD) process using diborane (B₂H₆) and silane gas (SiₓH_{y}), such as silane (SiH₄). The low-pressure chemical vapor deposition process may provide a uniform thin layer and a low defect rate, thereby improving the performance of the semiconductor device.

When boron (B) is applied as the first dopant, the boron-containing catalyst may be selected from the group including trimethyl borate (B(OCH₃)₃), boron trichloride (BCl₃), boron tribromide (BBr₃), boron dibromide (BBr₂), boron trifluoride (BF₃), and diborane (B₂H₆). In the case of a boron (B)-containing catalyst that does not contain hydrogen in itself, it may be supplied together with hydrogen (H₂).

Subsequently, referring to FIG. 4B, a second dopant, for example, arsenic (As), may be ion-implanted into the amorphous silicon layer including the first dopant. The second dopant may include a group-15 element of the periodic table, for example, nitrogen (N), phosphorus (P), or antimony (Sb) other than arsenic (As). Preferably, the first dopant may include boron (B), and the second dopant may include at least one selected from the group including phosphorus (P) and arsenic (As). The ion implantation of the second dopant may be performed in a direction substantially perpendicular to the surface of the substrate 200, and a tilted ion implantation may also be performed. The ion implantation process may be performed repeatedly several times. Electrical characteristics may be given to the semiconductor device that is fabricated by ion-implanting the second dopant, such as arsenic (As), into the amorphous silicon layer. The characteristics of the semiconductor device may be appropriately changed by changing the concentration of the second dopant that is ion-implanted. By adjusting the implantation energy and angle, it is possible to control the concentration of the dopant and have the dopant to penetrate to a desired depth. The dopant concentration may be adjusted according to the implantation conditions, such as energy, implantation time, and ion implantation rate. For example, the concentration may be adjusted from approximately 10% to 50% according to the implantation conditions. A high concentration of dopant may contribute to forming a current path more easily, but on the other hand, it may increase the leakage current, so it is desirable to control the dopant concentration in the above range. The ion implantation process may be repeatedly performed several times so that the dopant may be evenly distributed. The repetition of this process may ensure the conduction path to be formed more stably in the amorphous silicon layer.

The dopant ions implanted during the ion implantation process may impact the crystal structure in the silicon layer due to the high energy. In particular, when a group-15 element such as arsenic (As) or phosphorus (P) is implanted as a dopant into the amorphous silicon layer, a local re-crystallization phenomenon may occur at the implanted location. This re-crystallization may help to form a conduction path more easily. This may mainly function to make the conduction path more active and improve the conduction characteristics when the selector is in the on-state. The ion implantation process may control the electrical characteristics of the semiconductor device by implanting the second dopant into the amorphous silicon layer, and induce a conduction path to be formed by the implanted dopant. This may allow the selector to have the desired current-voltage characteristics and to form the conduction path more easily.

The ion implantation process of the second dopant described with reference to FIG. 4B may be omitted from the process of forming the selector pattern 240B in accordance with the embodiment of the present disclosure. That is, it is possible to fabricate a semiconductor device suitable for a particular purpose and characteristic only with the amorphous silicon layer into which the first dopant is implanted as the selector pattern 240B. However, when the second dopant is additionally implanted, the conduction path may be formed more easily, and thus the electrical characteristics of the selector may be enhanced.

Subsequently, referring to FIGS. 4C and 4D, the first dopant and/or the second dopant may be implanted into the initial selector layer 240 to form a selector layer 240A including the amorphous silicon layer containing the first dopant and/or the second dopant. The selector layer 240A may have a thickness of approximately 50 to 150 Å, preferably a thickness of approximately 80 to 120 Å, and more preferably a thickness of approximately 100 Å. When the thickness of the selector layer 240A is too thin, it may not trap sufficient charges, which may lower the resistance in the off-state and increase the leakage current. When the selector layer 240A is too thick, the conduction path may become excessively long in the on-state, which may reduce the current flow. When the thickness of the selector layer 240A is too thin, switching may become unstable, resulting in severe fluctuation in the resistance. When the thickness of the selector layer 240A is too thick, the switching rate may decrease. Since the selector layer 240A has a thickness of approximately 50 to 150 Å, the current flow may be optimized and the resistance may be effectively controlled by balancing the formation of the charge trap and the conduction path, and a fast switching rate may be maintained while ensuring a stable switching operation.

A barrier layer 241 including boron (B) may be formed over the selector layer 240A through a plasma treatment (see arrow \textcircled{1}). This plasma treatment may be performed by using a gas containing boron (B). For example, the plasma treatment may be performed by using one or more gases selected from the group including borane (BH₃), diborane (B₂H₆), trimethylborane (B(CH₃)₃), and boron trifluoride (BF₃).

The plasma treatment may be performed by plasma-assisted doping (PLAD) process, through which boron (B) may be implanted into the surface of a material layer for the boron barrier layer 241. In this process, the plasma may ionize the gas-state doping material and have the ions penetrate into the material layer for the boron barrier layer 241, thereby obtaining a desired doping concentration and characteristics. The PLAD process may be performed with a relatively low energy to minimize the surface damage and to form a uniform doping layer in the material layer for the boron barrier layer 241.

During this plasma treatment, a portion of the surface of the selector layer 240A that is exposed may be oxidized. The high energy state of the plasma and the gas used during the process may interact with each other, thereby forming an oxide on the surface of the selector layer 240A. The surface oxidation of the selector layer 240A may occur during the doping process, which may improve the stability and durability of the boron barrier layer 241.

The formed boron barrier layer 241 may function as a charge trap site, and in particular, the boron barrier layer 241 may activate a hole trap site to contribute to effectively capturing charges and controlling the operation characteristics of the selector layer 240A. When the hole trap site is activated, the migration path of electrons may be set more clearly to improve the electron mobility and make the current flow more smoothly. The boron barrier layer 241 may increase the initial resistance to decrease the leakage current in the off-state of the selector layer 240A and thereby improve the energy efficiency of the selector layer 240A. During the operation, the boron barrier layer 241 may utilize the trap site to form a conduction path more easily in the on-state, which may lower the threshold voltage level and make the selector layer 240A be switched at a lower voltage level. Furthermore, the boron barrier layer 241 may stably maintain the arsenic (As) profile of the selector layer 240A to maintain the performance of the selector layer 240A for a long time, and may further reduce the threshold voltage level Vₜₕ as an effect of interposing an auxiliary layer.

The boron barrier layer 241 may serve as a charge trap site and control the operation characteristics of the selector layer 240A. When the thickness of the boron barrier layer 241 is too thin, the charges may not be captured sufficiently, and conversely, when the thickness of the boron barrier layer 241 is too thick, the migration path of electrons may be excessively obstructed, reducing the conductivity. Therefore, the boron barrier layer 241 may preferably have a thickness of approximately 100 to 200 Å, and more preferably it may have a thickness of approximately 130 to 170 Å, and even more preferably, the boron barrier layer 241 may have a thickness of approximately 150 Å. This thickness may correspond to a thickness appropriate for maximizing the activation of this trap site and maintaining the migration path of electron. The boron barrier layer 241 may serve to protect the selector layer 240A from the external environment. When the thickness of the boron barrier layer 241 is too thin, the surface of the selector layer 240A may be easily damaged or oxidized. Therefore, it is preferred that the boron barrier layer 241 has a thickness of approximately 100 Å or more. Since the boron barrier layer 241 has a thickness of approximately 100 to 200 Å, stable and uniform doping may be ensured in the plasma treatment.

After forming the boron barrier layer 241, a thermal process on the amorphous silicon layer as the selector layer 240A may be performed below a temperature at which the amorphous silicon layer crystallizes. For example, the thermal process may be performed at a temperature of 400° C. or lower.

Referring to FIG. 4E, a second electrode layer 250, a memory layer 260, and a third electrode layer 270 may be formed over the boron barrier layer 241. The second electrode layer 250 and the third electrode layer 270 may be formed by a process of depositing a conductive material. The second electrode layer 250 may be realized as a single thin layer of titanium nitride (TiN), or the second electrode layer 250 may be realized by stacking a carbon (C) thin layer and a of titanium nitride (TiN) layer. Here, the carbon (C) thin layer may be formed at the interface between the boron barrier layer 241 and the titanium nitride (TiN) layer, thereby improving the interface characteristics between the electrodes. Further, a silicon nitride (SiN) thin layer may be formed between the first electrode layer 230 and the selector layer 240A, and a carbon (C) thin layer may be formed between the selector layer 240A and the second electrode layer 250.

The third electrode layer 270 may be formed over the second electrode layer 250 and the memory layer 260, and the third electrode layer 270 may be generally formed of a material that may withstand a high-temperature heat treatment and have excellent conductivity. The third electrode layer 270 may be formed by performing a metal deposition process or a sputtering process. To be specific, the third electrode layer 270 may be formed by depositing a conductive metal thin layer, such as titanium nitride (TiN), tungsten (W), copper (Cu), or aluminum (Al).

In the process of forming the third electrode layer 270, it is important to maintain high deposition uniformity and conductivity, and the metal layer may be formed to have a desired thickness through a process such as a plasma sputtering process or a Chemical Vapor Deposition (CVD) process. After the third electrode layer 270 is formed, an additional heat treatment or a patterning process may be performed to provide optimal electrical connection characteristics in the semiconductor device.

Referring to FIG. 4F, a hard mask layer 280 may be formed over the third electrode layer 270. The hard mask layer 280 may be formed by forming a material layer for the hard mask layer 280 and a photoresist pattern (not shown) and etching the material layer for the hard mask layer 280 with the photoresist pattern used as an etching barrier. The hard mask layer 280 may function as an etching barrier during the etching process for forming a memory cell MC, and the hard mask layer 280 may include diverse materials capable of securing an etching selectivity with respect to the memory cell MC. For example, the material layer for the hard mask layer 280 may have a single-layer structure or a multi-layer structure including diverse dielectric materials, such as silicon oxide, silicon nitride, and silicon oxynitride.

Referring to FIG. 4G, a memory cell MC including a third electrode pattern 270A, a variable resistance pattern 260A, a second electrode pattern 250A, a boron barrier pattern 241A, a selector pattern 240B, and a first electrode pattern 230A may be formed by using the hard mask layer 280 as an etching barrier and etching the third electrode layer 270, the memory layer 260, the second electrode layer 250, the boron barrier layer 241, the selector layer 240A, and the first electrode layer 230.

According to the embodiment of the present disclosure, the hard mask layer 280 may be removed in the process of etching the memory cell MC, but according to another embodiment of the present disclosure, part or all of the hard mask layer 280 may remain and then may be removed in a planarization process, which is described below.

Referring to FIG. 4H, an inter-layer dielectric layer 290 may be formed over the memory cell MC. The inter-layer dielectric layer 290 may be formed to have a thickness that may sufficiently fill the space between the memory cells MC and cover the upper portion. The inter-layer dielectric layer 290 may have a single-layer structure or a multi-layer structure including diverse dielectric materials, such as silicon oxide, silicon nitride, or a combination thereof.

Subsequently, a planarization process, such as a Chemical Mechanical Polishing (CMP) process, may be performed onto the inter-layer dielectric layer 290 until the upper surface of the memory cell MC is exposed. Even though the hard mask layer 280 is not completely removed but remains in the aforementioned process of etching the memory cell MC, the hard mask layer 280 may be removed because a planarization process is performed until the upper surface of the memory cell MC is exposed according to the embodiment of the present disclosure.

Subsequently, a plurality of second interconnections 220 extending in a second direction intersecting with the first direction, for example, the second direction shown in FIG. 1A while being coupled to the upper surface of the memory cell MC may be formed over the memory cell MC and the inter-layer dielectric layer 290. The second interconnections 220 may be formed by depositing a conductive material and patterning the conductive material, and the space between the second interconnections 220 may be filled with a dielectric material (not shown).

The semiconductor device in accordance with the embodiment of the present disclosure, as illustrated in FIG. 4H, may be fabricated by the process described above.

Referring back to FIG. 4H, the semiconductor device in accordance with the embodiment of the present disclosure may have a structure in which a boron barrier pattern 241A is disposed between the selector pattern 240B and the second electrode pattern 250A. The semiconductor device in accordance with the embodiment of the present disclosure may include a substrate 200, and a first interconnection 210, a first electrode pattern 230A, a selector pattern 240B, a boron barrier pattern 241A, a second electrode pattern 250A, a variable resistance pattern 260A, a third electrode pattern 270A, and a second interconnection 220 that are sequentially formed over the substrate 200.

The process structure of FIG. 4H may be substantially the same as the process structure of FIG. 1A which is described above. The substrate 200, the first interconnection 210, the first electrode pattern 230A, the selector pattern 240B, the boron barrier pattern 241A, the second electrode pattern 250A, the variable resistance pattern 260A, the third electrode pattern 270A, and the second interconnection 220 may respectively correspond to the substrate 100, the first interconnection 110, the first electrode layer 130, the selector layer 140, the boron barrier layer 141, the second electrode layer 150, the memory layer 160, the third electrode layer 170, and the second interconnection 120 illustrated in FIG. 1A. Therefore, a detailed description of the portion corresponding to the process structure of FIG. 1A described above will be omitted.

According to the embodiments of the present disclosure, the selector characteristics may be improved by forming a barrier layer containing boron in the upper or lower portion of the selector layer.

While the present invention has been described with respect to the specific embodiments, it will be apparent to those skilled in the art that various changes and modifications may be made without departing from the spirit and scope of the present disclosure as defined in the following claims. Furthermore, the embodiments may be combined to form additional embodiments.

What is claimed is:

1. A semiconductor device comprising a plurality of memory cells,
wherein each memory cell of said plurality of memory cells includes:
a memory layer;
a selector layer disposed over the memory layer to select the memory layer, the selector layer including an amorphous silicon layer including a dopant containing a group-13 element and a group-15 element of a periodic table; and
a barrier layer containing boron (B) disposed over or below the selector layer.

2. The semiconductor device of claim 1, wherein the dopant includes boron (B) and at least one of phosphorus (P) and arsenic (As).

3. The semiconductor device of claim 1, wherein the dopant includes arsenic (As) and boron (B).

4. The semiconductor device of claim 1, wherein the dopant has a concentration of 10 to 30 wt % in the amorphous silicon layer including the dopant.

5. The semiconductor device of claim 1, wherein the dopant has a concentration of 30 to 90 wt % in the amorphous silicon layer including the dopant.

6. The semiconductor device of claim 1, wherein the memory cell further includes:
a first electrode layer disposed below the selector layer; and
a second electrode layer disposed over the selector layer.

7. The semiconductor device of claim 6, wherein the first electrode layer and the second electrode layer include titanium nitride (TiN).

8. The semiconductor device of claim 6, further comprising:
a silicon nitride (SiN) thin layer disposed between the first electrode layer and the selector layer; and
a carbon (C) thin layer disposed between the selector layer and the second electrode layer.

9. The semiconductor device of claim 1, wherein the selector layer has a surface portion which is oxidized.

10. The semiconductor device of claim 1, wherein the barrier layer containing boron (B) has a thickness of 100 to 200 Å.

11. The semiconductor device of claim 1, wherein the selector layer has a thickness of 50 to 150 Å.

12. A method for fabricating a semiconductor device including a selector layer for controlling electrical access to a memory cell, the method comprising:
forming, as the selector layer, an amorphous silicon layer including a dopant over a substrate; and
forming a barrier layer containing boron (B) at an upper portion or a lower portion of the selector layer through a plasma treatment.

13. The method of claim 12, further comprising performing a thermal process on the amorphous silicon layer below a temperature at which the amorphous silicon layer crystallizes.

14. The method of claim 13, wherein the plasma treatment is performed by using a gas containing boron (B).

15. The method of claim 13, wherein the plasma treatment is performed by using one or more gases selected from a group including borane, diborane, trimethylborane, and boron trifluoride.

16. The method of claim 13, wherein forming the amorphous silicon layer including the dopant includes depositing a first dopant-doped amorphous silicon layer.

17. The method of claim 16, wherein depositing the first dopant-doped amorphous silicon layer is performed by a Low-Pressure Chemical Vapor Deposition (LPCVD) process using silane (SiH₄) and diborane (B₂H₆).

18. The method of claim 13, wherein the dopant has a concentration of 10 to 30 wt % in the amorphous silicon layer.

19. The method of claim 13, wherein the dopant has a concentration of 30 to 90 wt % in the amorphous silicon layer.

20. The method of claim 13, further comprising:
forming an electrode layer over the selector layer.

21. The method of claim 16, further comprising ion-implanting a second dopant into the first dopant-doped amorphous silicon layer.

22. The method of claim 21,
wherein the first dopant includes a group-13 element of a periodic table, and
wherein the second dopant includes a group-15 element of the periodic table.

23. The method of claim 21,
wherein the first dopant includes boron (B), and
wherein the second dopant includes at least one selected from a group including phosphorus (P) and arsenic (As).

24. The method of claim 13, wherein the thermal process is performed at a temperature of 400° C. or lower.
